(19) United States
(12) Patent Application Publication
(10) Pub. No.: US 2023/0386786 A1
(43) Pub. Date: Nov. 30, 2023

(54) GA IMPLANT PROCESS CONTROL FOR ENHANCED PARTICLE PERFORMANCE

(71) Applicant: Applied Materials, Inc., Santa Clara, CA (US)

(72) Inventors: Frank Sinclair, Hartland, ME (US); Bon-Woong Koo, Andover, MA (US); Tseh-Jen Hsieh, Rowley, MA (US); Gregory E. Stratoti, Haverhill, MA (US)

(73) Assignee: Applied Materials, Inc., Santa Clara, CA (US)

(21) Appl. No.: 18/303,370

(22) Filed: Apr. 19, 2023

Related U.S. Application Data
(60) Provisional application No. 63/346,034, filed on May 26, 2022.

(51) Int. Cl. H01J 37/317

(52) U.S. Cl. CPC H01J 37/3171; H01J 2237/31703; H01J 2237/006; H01J 2237/022

(57) ABSTRACT

A method of reducing gallium particle formation in an ion implanter. The method may include performing a gallium implant process in the ion implanter, the gallium implant process comprising implanting a first dose of gallium ions from a gallium ion beam into a first set of substrates, while the first set of substrates are disposed in a process chamber of the beamline ion implanter. As such, a metallic gallium material may be deposited on one or more surfaces within a downstream portion of the ion implanter. The method may include performing a reactive gas bleed operation into at least one location of the downstream portion of the ion implanter, the reactive bleed operation comprising providing a reactive gas through a gas injection assembly, wherein the metallic gallium material is altered by reaction with the reactive gas.

### CROSS-REFERENCE TO RELATED APPLICATION

The present application claims priority to U.S. Provisional patent application Ser. No. 63/346,034, filed May 26, 2022, entitled “GA IMPLANT PROCESS CONTROL FOR ENHANCED PARTICLE PERFORMANCE”, and incorporated by reference herein in its entirety.

### BACKGROUND

As the dimensions of FinFET devices, including the width and spacing continues to decrease, device properties such as contact resistivity and on/off current ratios become more challenging to improve. One approach to address this problem is to employ a Ga implantation process using Ga ions for creation of p-type SiGe source/drain ohmic contacts, instead of the more common Boron implant. This approach has been observed to substantially reduce contact resistivity, due in part to Ga being two orders of magnitude more soluble in Ge relative to B. One type of ion source suitable for generation Ga ions employs a Ga₂O₃ target, a nonvolatile solid precursor. This approach may enable extended high dose Ga implantation.

One main challenge for Ga implantation using a solid Ga₂O₃ target is the observation of Ga spherical particles on a substrate; where such particles may persist even after an ashing strip process is performed. The presence of these particles may lead to a “small unetch defect” during the next process step, which defect may cause a given device failure and therefore represent yield loss.

It is with respect to these and other considerations that the present improvements may be useful.

### BRIEF SUMMARY

In one embodiment, a method of reducing gallium particle formation in an ion implanter is provided. The method may include performing a gallium implant process in the ion implanter, the gallium implant process comprising implanting a first dose of gallium ions from a gallium ion beam into a first set of substrates, while the first set of substrates are disposed in a process chamber of the beamline ion implanter. As such, a metallic gallium material may be deposited on one or more surfaces within a downstream portion of the ion implanter. The method may include performing a reactive gas bleed operation into at least one location of the downstream portion of the ion implanter, the reactive bleed operation comprising providing a reactive gas through a gas injection assembly, wherein the metallic gallium material is altered by reaction with the reactive gas.

In another embodiment, a beamline ion implanter, arranged for implanting gallium ions into a substrate is provided. The beamline ion implanter may include an ion source to generate a gallium ion beam, comprising a dose of gallium ions, and may further include a downstream portion of the beamline ion implanter, to receive the gallium ion beam. The downstream portion may include a process chamber, disposed to accommodate a substrate holder, and a dose cup chamber, disposed downstream of the process chamber. The dose cup chamber may include a dose cup, positioned to intercept the gallium ion beam when the substrate holder is not situated in a central part of the process chamber. The downstream portion may also include a gas injection assembly, disposed to performing a reactive gas bleed operation into at least one location of the downstream portion of the ion implanter.

In another embodiment, a method of reducing gallium particle formation in an ion implanter may include. The method may include performing a gallium implant process in the ion implanter. The gallium implant process may include implanting a first dose of gallium ions into a first set of substrates, while the first set of substrates are disposed in a process chamber of the beamline ion implanter, wherein a metallic gallium material is deposited on one or more surfaces within a downstream portion of the ion implanter. The method may include performing a reactive implant process to implant phosphorous-containing ions, nitrogen-containing ions, or a combination thereof into the process chamber, wherein the metallic gallium material is transformed to a gallium compound layer containing phosphorous, nitrogen, or a combination thereof.

### BRIEF DESCRIPTION OF THE DRAWINGS

FIG. 1 illustrates an embodiment of implanting a semiconductor device using Ga ions;

FIG. 2A illustrates a side view of an exemplary Ga ion source;

FIG. 2B illustrates an image on an exemplary Ga ion source chamber;

FIGS. 3A-3F illustrate the results of analysis of Ga particle generation that may take place after Ga ion implantation;

FIG. 4A is a schematic illustration of Ga layer formation;

FIG. 4B is a schematic illustration of Ga particle formation from the Ga layer of FIG. 4A;

FIG. 5 is a composite illustration depicting gas introduction into a portion of an ion implanter beamline, according to embodiments of the disclosure;

FIG. 6 presents an exemplary process flow; and

FIG. 7 presents another exemplary process flow.

### DETAILED DESCRIPTION

Techniques for decreasing particle yield using a solid target ion source for Gallium (Ga) implantation are disclosed herein.

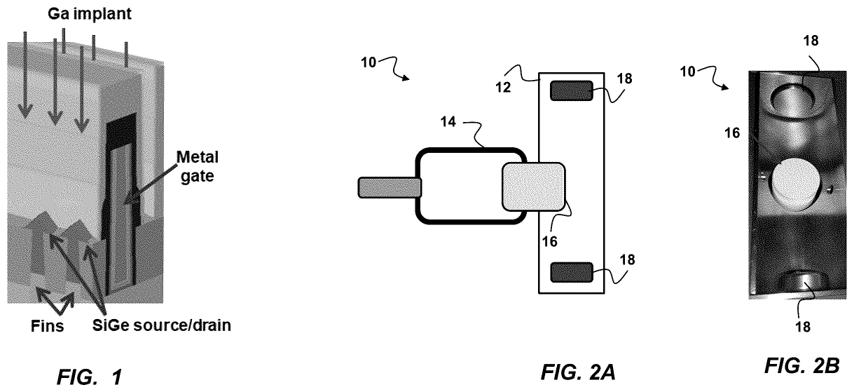

FIG. 1 illustrates an embodiment of implanting a semiconductor device using Ga ions. In the example shown, a transistor structure, including metal gate, semiconductor fins, and SiGe source/drain is shown. The transistor structure may be subjected to a gallium implant from a gallium ion beam in a beamline ion implanter. According to various embodiments, a beamline implanter may include a gallium ion source, and various known beamline components to shape, accelerate/decelerate, filter, and steer an ion beam to a substrate stage in a process or substrate chamber where Gallium implantation is to take place. As such, various surfaces within the beamline of the beamline ion implanter may be susceptible to accumulation of gallium.

FIG. 2A illustrates a side view of an exemplary Ga ion source that may be used for implanting a semiconductor device with Ga ions. FIG. 2B shows an image of an exemplary Ga ion source chamber for generating Ga ions for implantation. The Ga ion source, shown as ion source 10, employs a solid target, such as Ga₂O₃, to form a source of gallium ions. The ion source 10 includes a target holder 14, for holding a solid Ga target 16. The target holder 14 may be translatable to move the solid Ga target 16 into and out of the ion source chamber 12. In this example, the ion source chamber 12 may include repellers 18 and may function as a known indirectly heated ion source.

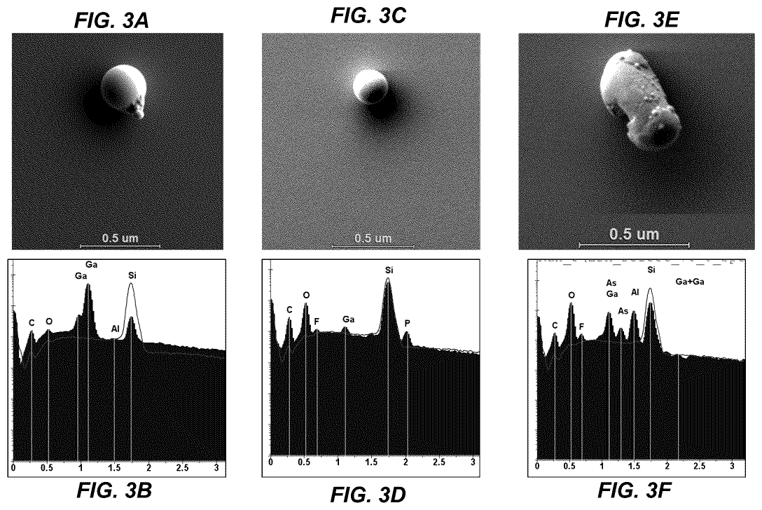

The present inventors have discovered that using known beamline ion implantation approaches for implanting Ga, solid gallium particle accumulation may take place at some locations in a beamline. FIGS. 3A-3F illustrates analysis of Ga particle generation that takes place after Ga ion implantation is performed in a beamline ion implanter. For example, the ion source 10 will generate gallium ions that are transported through various beamline components while travelling toward a substrate to be implanted. In addition to implanting into a substrate, gallium ions may condense on other surfaces of the beamline ion implanter. Due to the limited solubility (˜6E16 cm⁻²), low melting point, high surface tension between gallium to either silicon or graphite surfaces, the excess gallium spherical defects will precipitate on the surface based on the overall accumulated gallium dose. Condensation of gallium may eventually lead to aggregation into solid particles. In FIG. 3A, FIG. 3C, and FIG. 3E there are shown three different microscopic particles, collected on a surface of a silicon wafer, after the silicon wafer was subjected to implantation with a Ga ion beam for approximately 50 hours.

The micrograph images show that these particles are generally spherical particles, or not very elongated, in the case of FIG. 3E. The particles size in the examples shown is between 0.2 pm and 0.4 μm.

Turning now to FIG. 3B in particular, there is shown an energy dispersive X-ray (EDX) spectrum of the particle of FIG. 3A. The spectra is collected by placing an electron beam over the particle in question, and recording the energy spectra generated by excitation of atoms within the particle. The spectrum shows a series of peaks, corresponding to different energies that are characteristic of different elements, as labeled. The spectrum also includes a reference line, characteristic of silicon, indicative of the silicon substrate. In FIG. 3B, a series of peaks are illustrated, from left, carbon, oxygen, gallium, and silicon. The large peak at the energy corresponding to gallium indicates that the particle is composed predominantly of gallium. This finding is consistent with the morphology of the particle of FIG. 3A, whose spherical shape suggests formation by an agglomeration process. Note that the melting temperature of elemental gallium is near room temperature, being 30° C.

Turning now to FIG. 3D in particular, there is shown an energy dispersive X-ray (EDX) spectrum of the particle of FIG. 3C . In this example, the peaks of FIG. 3B are also present, in addition to a small F peak and small P peak. In addition, the relative intensity of the Ga peak is reduced with respect to the Ga peak of FIG. 3B, while the relative intensity of the Si peak is increased. These results may be partially explained by the relatively smaller size of the particle of FIG. 3C with respect to the particle of FIG. 3A. Note that because of the finite size of the electron beam generating the spectra, the electron beam may be more or less attenuated within a given particle, depending upon the particle size. As a result, the smaller the particle size, the more radiation generated by material outside of the particle will be collected in a given spectrum. Additionally, the particle shown may include relatively smaller proportion of Ga in comparison to other elements, including C, O, and P.

Turning now to FIG. 3F in particular, there is shown an energy dispersive X-ray (EDX) spectrum of the particle of FIG. 3E. In this example, the peaks of FIG. 3D are also present. In addition, the relative intensity of the Ga peak is increased with respect to the Ga peak of FIG. 3D, while the relative intensity of the Si peak is decreased. Again, these results may be explained by the relatively larger size of the particle in FIG. 3E compared with the particle of FIG. 3C.

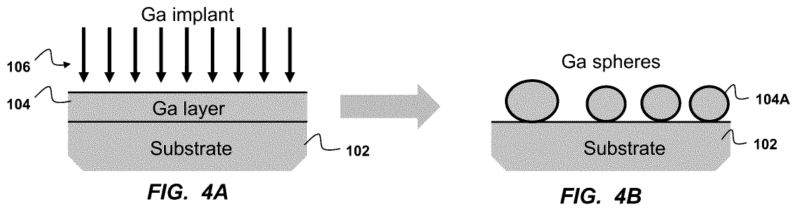

By way of explanation of the results of FIGS. 3A-3F, and without limitation as to any particular theory, the repeated use of Ga implant produces may produce a layer of pure Ga on a given surface within a beamline. In FIG. 4A there is shown a substrate 102, subject to gallium ions 106, where, after sufficient gallium ion flux has reached a substrate 102. In this case, a gallium layer, shown as layer 104, is formed. On relatively colder (−80° C. for example) surfaces, this layer 104 will be a solid, but when warmed up (>30° C.), this layer will become a liquid, which liquid may well “ball up” to make many spherical shapes. This process is shown to the right in FIG. 4B, where the layer 104 is transformed to the spherical particles 104A of gallium. Note that the process of FIGS. 4A and 4B may also take place on other surfaces within a beamline ion implanter, besides the surface of a substrate being implanted. The temperature effect during preventative maintenance may influence the formation of spherical Ga defect formation. In one example, while shown as two separate structures, the process in FIGS. 4A and FIG. 4B may take place at the same time when a layer of sub-layer of gallium deposits on surfaces in an ion implanter that are at room temperature (25 C) or above. Thus, depositing Ga species on room temperature or hotter surfaces may tend to agglomerate into particles with or without ever forming continuous films. Also, areas in a given ion implanter beamline, especially in the process chamber where a heavy deposit of Ga layer may accumulate, when hit by ion beams during a conditioning period may also influence the formation of Ga defects. In particular, Ga defects after formation, may migrate to different areas in downstream areas of a beamline, such as at the stage of an electrostatic energy filter, plasma flood gun, process chamber where substrate implantation takes place, or dose cup region. As a result, even though the dose of ions in a given ion implantation procedure performed on a given wafer may not be sufficient to generate such Ga particles, such particles may nevertheless migrate onto the substrate from nearby surfaces of the beamline, having been formed from the accumulation of Ga material generated in previous implantation processes.

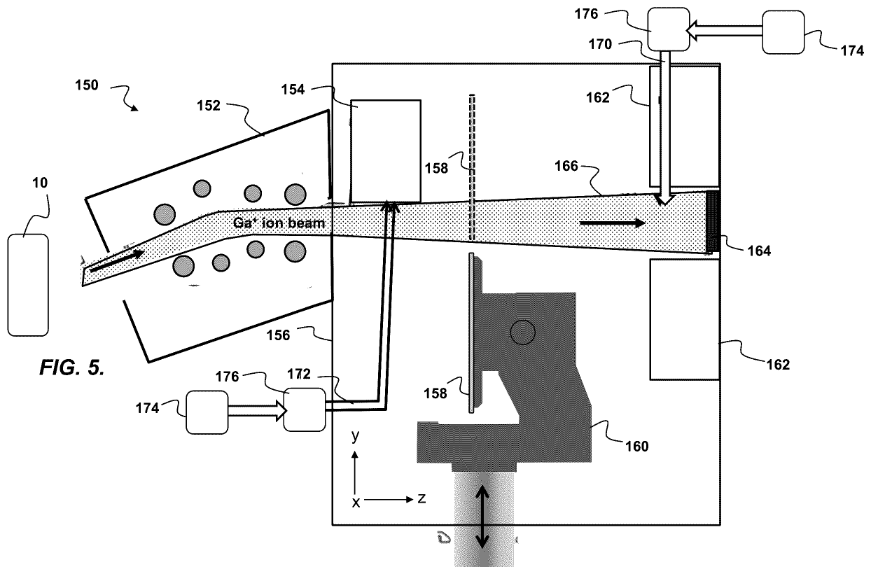

To address this defect formation problem, embodiments of the disclosure employ process steps that can alter a Ga layer formed as a result of Ga implantation, and therefore may prevent the formation of Ga spherical particles. FIG. 5 is a composite illustration showing a downstream portion of a beamline ion implanter 150, used for implanting Ga into a substrate, in accordance with embodiments of the disclosure. The beamline ion implanter 150 may employ an ion source 10 as described previously. FIG. 5 also depicts gas introduction into various locations in the downstream portion of the beamline ion implanter 150, according to embodiments of the disclosure. In this example, an electrostatic energy filter 152 and a plasma flood gun 154 are shown in cross-section, with a process chamber 156, downstream of the plasma flood gun 154. As shown, the gallium ion beam 166 is conducted through the beamline ion implanter 150 toward a location in the process chamber 156, where a substrate 158 may be housed.

As shown in FIG. 5, the substrate 158 may be transported on a substrate holder 160, so as to scan the substrate 158 along the Y-axis of the Cartesian coordinate system shown, in one example. As such, Ga implantation into the substrate 158 may take place when the substrate 158 intercepts the gallium ion beam 166. In various embodiments, one or more gas injection assemblies may be provided, such as locations near the process chamber 156, where the injection assembly may include an injection port, tubes, conduits, valves, and so forth, to provide and conduct a designated gas into the beamline ion implanter 150. In the example shown, an injection assembly 172 is located downstream of the electrostatic energy filter 152, and near the plasma flood gun 154. The injection assembly 172 may act as a plasma flood gun injection assembly to inject gas directly into the plasma flood gun 154, such as at the bottom of the plasma flood gun 154 as viewed in FIG. 5, or adjacent to the plasma flood gun 154, for example.

Note that the present inventors have discovered that elemental gallium particles may be found in hidden areas of the beamline of a beamline ion implanter, such as near or in the plasma flood gun. In other words, even in surfaces not directly exposed to gallium ions during implantation, gallium particles may migrate to these surfaces after formation at another location via sputtering or interaction with an ion beam. Thus, layers that initially form as elemental Ga layers on a given beamline surface, may agglomerate and transform into sub-micrometer sized particles that may then be readily transported to additional surfaces, including surfaces where such contamination may not have previously been contemplated. Such hidden locations may then serve as sources for subsequent wafer contamination as the hidden particles are transported to the substrate during processing. Thus, provision of a local reactive gas may be useful, such as N₂ or PH₃ in order to react elemental gallium metallic material, such as Ga layers or other Ga material, in regions such as near a plasma flood gun. The reaction of the metallic gallium material may transform these layers into more stable compound layers (e.g., GaN, GaP) may interrupt the formation and migration of Ga particles to surfaces that may be otherwise cumbersome to clean. As used herein, “GaN” or “GaP” may refer to a mixture of gallium and nitrogen or mixture of gallium and phosphorous, respectively, where the mixture is a compound, and alloy, an amorphous material, a partially crystalline material, a mixture of variable composition. Such a mixture may generally have a much higher thermal stability than elemental metallic gallium, and may have a melting temperature of many hundreds of degrees C., for example, therefore avoiding melting and formation of gallium-containing spherical particles. Note that in accordance with some embodiments, N₂ or PH₃ may be flowed through an optional, external plasma source, shown as plasma source 176, to impart more reactivity to these gases in order to more readily react with gallium metallic material.

The beamline ion implanter may include additionally to, or instead of the injection assembly 172, an injection assembly 170. In this example, the injection assembly 170 is arranged as a dose cup injection assembly to inject gas into a dose cup chamber 162 that is located downstream of the substrate holder 160. Note that the dose cup chamber 162 includes a dose cup that is positioned to intercept the gallium ion beam 166. A function of the dose cup 164 is to measure the current of the gallium ion beam 166 so that implantation processing may be properly monitored and controlled.

In various embodiments, a gas injection assembly, such as injection assembly 170 or injection assembly 172, may include gas line to conduct a reactive gas, valves to control the flow of the reactive gas, as well as a reactive gas source, shown as gas source 174. The gas source 174 may be a single source, coupled to multiple injection assemblies, or may represent a dedicated gas source coupled to just one injection assembly, such as injection assembly 172.

According to embodiments of the disclosure, the gas injection through injection assembly 170 or injection assembly 172 may take place in-situ or periodically. In an example of periodically performing the gas injection, after processing a given number of wafers using gallium ion beam implantation, wafer processing is halted, and gas injection commenced, such as while the ion beam in maintained ON. In other words, the periodic gas injection may involve directing gallium ions of an ion beam to an empty substrate holder, to a dummy wafer, located on a substrate holder, or to a dose cup, for example, while a reactive gas is admitted to the downstream portion of the implanter. An example of in-situ gas injection is when the given gas is injected during wafer processing, meaning during Ga implantation into the given wafer, where the gallium ion beam is maintained in an ON state during gas injection.

In one embodiment, a nitrogen bleed operation may be performed in-situ or periodically through one or both of the injection assembly 170 and injection assembly 172. In this manner elemental gallium material forming on surfaces in various locations near the substrate 158 may be transformed, such as in the dose cup chamber 162, plasma flood gun 154 or surfaces within process chamber 156. As such, the injection of nitrogen may alter the formation of gallium layers, transforming a gallium metal layer into a treated layer, represented as a GaN layer, where the GaN layer is a non-metallic material having a relatively higher melting temperature compared with elemental gallium, such as at least several hundreds of degrees Celsius. As such, the treated layer may be much less likely to agglomerate and form particulates that can cause contamination within the beamline ion implanter 150.

In another embodiment, a PH₃ bleed operation may be performed in-situ or periodically through one or both of the injection assembly 170 and injection assembly 172. In this manner elemental gallium material forming on surfaces in various locations near the substrate 158 may be transformed, such as in the dose cup chamber 162, plasma flood gun 154 or surfaces within process chamber 156. In particular, the injection of PH₃ may alter the formation of gallium layers, transforming a gallium metal layer into a treated layer, represented as a GaP layer, where the GaP layer is a non-metallic material having a relatively higher melting temperature compared with elemental gallium, such as at least several hundreds of degrees Celsius. As such, the treated layer may be much less likely to agglomerate and form particulates that can cause contamination within the beamline ion implanter 150.

Non-limiting examples of suitable gases for injection assembly 170 or injection assembly 172 include nitrogen, such as N₂, or phosphorous containing gas, such as PH₃. In some embodiments, gas injection may be performed after intervals of implantation, such as every 12 hours or every 24 hours, to mitigate formation of Ga spherical particles. For example, the present inventors have observed that Ga spherical particles may be generated after operating a gallium ion implanter for approximately 20 hours. In particular, for in-situ gas injection, gas may be injected at a flow rate of 1 sccm to 10 sccm, while for periodic gas injection a suitable gas flow rate may be 1 sccm to 20 sccm. For periodic gas injection between intervals of implantation, for a gas flow of 1 sccm to 20 sccm, for example, gas injection may last for 30 minutes to 2 hours in some non-limiting embodiments.

Some of these embodiments may also entail hardware installation in a source gas box (not shown), and hardware modification in the dose cup 164 area, in order to enable gas bleed.

In another embodiment, a periodic Nitrogen implant may be employed in the beamline ion implanter 150 to convert a gallium elemental layer into a GaN layer. In another embodiment, during a tool recovery interval, Nitrogen/Phosphorous conditioning ion beams may be introduced in order to modify a Ga deposit layer into Ga—P or GaN layer. According to various embodiments, the nitrogen or phosphorous ion beams may be used to convert deposited Ga material in a dose cup, a substrate holder and/or a plasma flood gun area into material such as Ga—P or GaN. As an example, a dummy substrate may be placed on a substrate holder and nitrogen or phosphorous ion beam initiated to implant N or P for a designated time period to convert Ga residual material on the substrate holder, dose cup, and plasma flood gun into the more thermally stable GaP or GaN compounds.

FIG. 6 provides an exemplary process flow 600. At block 602, a gallium ion beam is generated at an ion source of a beamline ion implanter. In one non-limiting example, the ion source may be an indirectly heated cathode ion source, using, for example, a gallium oxide target.

At block 604, a first does of gallium ions from the gallium ion beam is implanted into a first set of substrates. The gallium ions may be implanted when one or more substrates are provided in serial fashion into a central region of a process chamber located in a downstream portion of the beamline ion implanter. As such, metallic gallium material may be deposited on one or more surfaces within the downstream portion. In particular, on relatively colder surfaces, a continuous metallic Ga layer may accumulate, such as surfaces of the downstream portion that are maintained below 30 C.

At block 606 a reactive gas is provided through a gas injection assembly that is located in the downstream portion of the beamline ion implanter. As such, the metallic gallium material is altered by reaction with the reactive gas. In some examples the reactive gas may be N₂ or PH₃. In some examples, the gas injection assembly may be located in a dose cup chamber located downstream of the process chamber, and/or is located at a plasma flood gun, upstream of the process chamber. As such, the metallic gallium material is altered by reaction with the reactive gas. In one example, the metallic gallium material may be transformed into a Ga—N material that is resistant to agglomeration, and may have a much higher melting temperature than gallium metal, such as many hundreds of degrees C. In another example, the metallic gallium material may be transformed into a Ga—P material that is resistant to agglomeration, and may have a much higher melting temperature than gallium metal, such as many hundreds of degrees C.

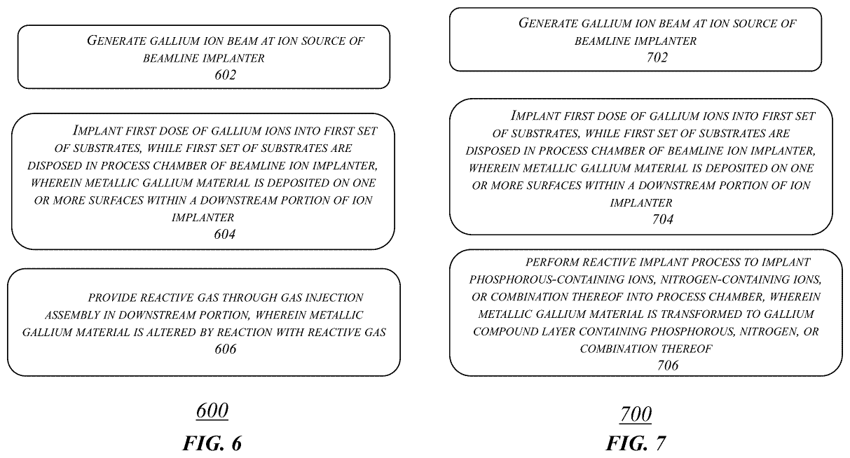

FIG. 7 provides an exemplary process flow 700. At block 702, a gallium ion beam is generated at an ion source of a beamline ion implanter. In one non-limiting example, the ion source may be an indirectly heated cathode ion source, using, for example, a gallium oxide target.

At block 704, a first does of gallium ions from the gallium ion beam is implanted into a first set of substrates. The gallium ions may be implanted when one or more substrates are provided in serial fashion into a central region of a process chamber located in a downstream portion of the beamline ion implanter. As such, metallic gallium material may be deposited on one or more surfaces within the downstream portion. In particular, on relatively colder surfaces, a continuous metallic Ga layer may accumulate, such as surfaces of the downstream portion that are maintained below 30 C.

At block 706, a reactive implant process is performed in the beamline ion implanter, to implant phosphorous-containing ions, nitrogen-containing ions, or a combination of phosphorous-containing ions and nitrogen-containing ions. As such, the metallic gallium material may be transformed into a Ga—N material that is resistant to agglomeration, and may have a much higher melting temperature than gallium metal, such as many hundreds of degrees C. In another example, the metallic gallium material may be transformed into a Ga—P material that is resistant to agglomeration, and may have a much higher melting temperature than gallium metal, such as many hundreds of degrees C.

In summary, the present embodiments provide a first advantage of reducing or preventing gallium particle formation on surfaces such as substrate surfaces that may occur after gallium implantation, such as using a solid target Gallium ion source. As a second advantage, the present embodiments may reduce the necessity or frequency of expensive beamline maintenance procedures to compensate for gallium particle formation that otherwise may occur as a result of gallium ion implantation.

While the present disclosure makes reference to certain embodiments, numerous modifications, alterations and changes to the described embodiments are possible without departing from the sphere and scope of the present disclosure, as defined in the appended claim(s). Accordingly, it is intended that the present disclosure not be limited to the described embodiments, but that it has the full scope defined by the language of the following claims, and equivalents thereof.

What is claimed:

1. A method of reducing gallium particle formation in an ion implanter, comprising:
performing a gallium implant process in the ion implanter, the gallium implant process comprising implanting a first dose of gallium ions from a gallium ion beam into a first set of substrates, while the first set of substrates are disposed in a process chamber of the ion implanter, wherein a metallic gallium material is deposited on one or more surfaces within a downstream portion of the ion implanter; and
performing a reactive gas bleed operation into at least one location of the downstream portion of the ion implanter, the reactive bleed operation comprising providing a reactive gas through a gas injection assembly, wherein the metallic gallium material is altered by reaction with the reactive gas.

2. The method of claim 1, wherein the reactive gas comprises N₂ or PH₃, or a combination thereof, and wherein the metallic gallium material forms a Ga—N material, a Ga—P material, or a combination thereof.

3. The method of claim 1, wherein the downstream portion of the ion implanter comprises an electrostatic energy filter, a plasma flood gun, and a dose cup chamber.

4. The method of claim 3, wherein the gas injection assembly comprises a dose cup injection assembly, located in the dose cup chamber.

5. The method of claim 3, wherein the gas injection assembly comprises a plasma flood gun injection assembly, located at the plasma flood gun.

6. The method of claim 1, wherein the reactive gas bleed operation is performed in an in-situ manner during the gallium implant process.

7. The method of claim 6, wherein a flow rate of the reactive gas is between 1 sccm and 10 sccm.

8. The method of claim 1, wherein the reactive gas bleed operation is periodically in the ion implanter.

9. The method of claim 8, wherein a flow rate of the reactive gas is between 1 sccm to 20 sccm.

10. The method of claim 8, wherein the reactive gas bleed operation is performed while the gallium ion beam in maintained in an ON state.

11. The method of claim 1, wherein the gallium implant process is a first gallium implant process, the method further comprising performing a second gallium implant process after the reactive gas bleed operation, while not venting the ion implanter for maintenance between the first gallium implant process and the second gallium implant process, the second gallium implant process comprising implanting a second dose of gallium ions into a second set of substrates, while the second set of substrates are disposed in the process chamber.

12. A beamline ion implanter, arranged for implanting gallium ions into a substrate, comprising:
an ion source to generate a gallium ion beam, comprising a dose of gallium ions; and
a downstream portion of the beamline ion implanter, to receive the gallium ion beam, the downstream portion comprising:
a process chamber, disposed to accommodate a substrate holder; and
a dose cup chamber, disposed downstream of the process chamber, the dose cup chamber comprising a dose cup, positioned to intercept the gallium ion beam when the substrate holder is not situated in a central part of the process chamber; and
a gas injection assembly, disposed to performing a reactive gas bleed operation into at least one location of the downstream portion of the ion implanter.

13. The beamline ion implanter of claim 12, the downstream portion further comprising a plasma flood gun.

14. The beamline ion implanter of claim 12, the gas injection assembly being coupled to deliver a reactive gas into the downstream portion, the reactive gas comprising N₂ or PH₃ or a combination thereof.

15. The beamline ion implanter of claim 13, wherein the downstream portion of the ion implanter comprises an electrostatic energy filter, disposed upstream to the plasma flood gun.

16. The beamline ion implanter of claim 12, wherein the gas injection assembly comprises: a dose cup injection assembly, located in the dose cup chamber.

17. The beamline ion implanter of claim 13, wherein the gas injection assembly comprises a plasma flood gun injection assembly, located at the plasma flood gun.

18. A method of reducing gallium particle formation in an ion implanter, comprising:
performing a gallium implant process in the ion implanter, the gallium implant process comprising implanting a first dose of gallium ions into a first set of substrates, while the first set of substrates are disposed in a process chamber of the ion implanter, wherein a metallic gallium material is deposited on one or more surfaces within a downstream portion of the ion implanter; and
performing a reactive implant process to implant phosphorous-containing ions, nitrogen-containing ions, or a combination thereof into the process chamber, wherein the metallic gallium material is transformed to a gallium compound layer containing phosphorous, nitrogen, or a combination thereof.
